(19) United States
(12) Patent Application Publication
(10) Pub. No.: US 2007/0172979 A1
(43) Pub. Date: Jul. 26, 2007

(54) Method of manufacturing electronic device using ink-jet method

(76) Inventors: Shoichi Uchino, Annaka (JP); Akiko Iwata, Suginami (JP); Yoshihiro Arai, Mobara (JP); Hitoshi Azuma, Yokohama (JP); Tomio Yaguchi, Sagamihara (JP)

Correspondence Address: REED SMITH LLP, Suite 1400, 3110 Fairview Park Drive, Falls Church, VA, 22042, US

(21) Appl. No.: 11/655,058

(22) Filed: Jan. 19, 2007

(30) Foreign Application Priority Data
Jan. 20, 2006 (JP) 2006-012363

(51) Int. Cl. H01L 51/40

(52) U.S. Cl. 438/99

(57) ABSTRACT

The present invention relates to a manufacturing method which uses an ink jet method for forming various kinds of thin films in an electronic device such as an organic EL panel or an organic thin film transistor and ink suitably used in the method. The manufacturing method manufactures an electronic device such as an organic layer which forms a pixel portion of a hole injection layer or the like of an organic EL panel or an active layer of an organic thin film transistor using ink composition which is formed by adding tertiary-alcohol into ink which uses water as a main solvent. As the tertiary-alcohol, 3-methyl-1-butyn-3-ol may be used. An addition quantity of alcohol with respect to ink is set to a value which falls within a range from approximately 25wt % to 40wt %.

### CROSS-REFERENCE TO RELATED APPLICATIONS

The disclosure of Japanese Patent Application No. P2006-12363 filed on Jan. 20, 2006(yyyy/mm/dd) including the claims, the specification, the drawings and the abstract is incorporated herein by reference in its entirety.

### BACKGROUND OF THE INVENTION

1. Field of the Invention

The present invention relates to a manufacturing method of an electronic device, and more particularly to the formation and a material of active regions of an electronic device and, to be more specific, for example, a method for coating a light emitting layer of an organic EL panel or an electrode made of a semiconductor or a semiconductor layer of an organic thin film transistor and the like by an ink jet method, and ink composition suitable for such coating.

2. Description of the Related Arts

In manufacturing a polymer-based electroluminescence panel (organic EL display device, hereinafter also simply referred to as organic EL panel or OLED) which is expected to be applied to a large-sized panel display (hereinafter, panel display being also simply referred to as panel) or a constituting layer of various kinds of electronic devices including a semiconductor element such as a thin film transistor or the like, the application of an ink jet method (IJ method) has been considered. The ink jet method is a coating method which is suitable for forming a uniform thin film in a fine region. For example, in the full-color organic EL panel, in general, one color pixel (pixel) is constituted of respective sub pixels of three colors consisting of R, G and B.

At present, in manufacturing the full-color organic EL panel, a so-called low-molecular-based organic EL method in which respective low-molecular light-emitting materials which constitute sub pixels of three colors consisting of R, G and B are applied for respective sub pixels in division using a vacuum mask vapor deposition method is considered prominent. This method, however, has drawbacks such as (1) the positional accuracy of mask vapor deposition is low and hence, the manufacture of an organic EL panel which is applicable to a large-sized is play is difficult, (2) the utilization efficiency of light-emitting-layer forming materials including light emitting materials is low, and (3) the productivity is low.

To the contrary, a polymer organic EL panel in which respective polymer light-emitting materials of three colors consisting of R, G and B are applied in division using a printing method such as an ink-jet method exhibits high positional accuracy, the high material utilization efficiency, the high productivity and the like in the formation of the light emitting layers of three colors consisting of R, G and B and hence, the application of the polymer organic EL panel to a large-sized panel is expected. Although the polymer organic EL panel has the above-mentioned advantageous effects, it is difficult to form the light emitting layer having the highly uniform film thickness, particularly a hole injection layer having the highly uniform film thickness.

In a pixel part of the organic EL panel, the light emitting layer including a hole injection layer formed of an organic layer and an electron injection layer are stacked on one electrode (first electrode, here, anode), and another electrode (second electrode, here, cathode) is formed on an uppermost layer as a film. Then, it is preferable to use an ink-jet method for the formation of the organic layer (particularly, the hole injection layer to satisfy a demand for the uniformity of film thickness).

The hole injection layer which constitutes the pixel portion of the polymer-based organic EL panel is formed into a thin film by ejecting water-based ink which uses water as a main solvent to the pixel portion from a nozzle of an ink jet device and by drying the water-based ink. In the formation of the thin film using such an ink jet device, the water-based ink is liable to be easily clogged at an ejection end of the nozzle and hence, it is difficult to form a device portion having the hole injection layer which is uniform and has no depletion over the whole surface of a display region of the organic EL panel. Further, when the water-based ink is used, ink liquid droplets which are ejected from the nozzle do not spread uniformly in a wet state on an electrode of the pixel portion (here, an anode made of ITO).

FIG. 11A to FIG. 11C are schematic views for explaining steps in which ink clogging is generated in the nozzle of the ink jet device, wherein FIG. 11A is a front view of the nozzle, FIG. 11B is a cross-sectional view taken along a line A-A′ in FIG. 11A, and FIG. 11C is a cross-sectional view similar to the FIG. 11B showing a state in which the ink is clogged in the nozzle. A nozzle portion of the ink jet device is constituted by arranging a plurality of nozzles NZL on the same plane, wherein by applying a voltage to a piezoelectric plate mounted on a back surface of the nozzle NZL, ink liquid droplets are ejected from a distal end of the nozzle NZL. Here, some ink liquid droplets may remain on the arrangement surface without being separated from the distal end of the nozzle NZL. FIG. 1A shows a state in which ink remains so as to make four nozzles communicate with each other. At this point of time, ink is still in a liquid form and the ink in a liquid form is indicated by symbol INK(L) in the drawing. Along with a lapse of time, a solvent contained in the ink INK(L) in a liquid form is vaporized and is solidified as shown in FIG. 11C thus clogging the nozzle NZL. This clogging becomes cause of interrupting the formation of the uniform film thickness.

In patent document 1, there is the description that surface tension and viscosity of the hole injection layer are controlled by forming a material of the hole injection layer by adding lower alcohol such as methylalcohol, ethylalcohol or isopropylalcohol to PEDOT (polyethylenedioxythiophene) and PSS (aqueous colloid solution of poly (styrenesulfonic acid)). Further, lower alcohol such as methylalcohol, ethylalcohol or isopropylalcohol is highly volatile and hence, when an addition quantity of the lower alcohol is large, clogging of the nozzle is generated whereby it is desirable to set an addition quantity of lower alcohol to approximately 20 wt % or less.

Further, in patent document 2, there is the description that tertiary-butylalcohol is contained in water-based ink used in a general ink-jet method as tertiary-alcohol.

[Patent document 1] JP-A-2000-323276

[Patent document 2] JP-A-07-082499

[Non-Patent document 1] “OYO BUTSURI (Applied Physics)” published by the Physical Society of Japan vol.70, No.12, pages 1452 to 1455

### SUMMARY OF THE INVENTION

The reason that the organic layer, for example, the hole injection layer having high film thickness uniformity cannot be formed lies in that the hole injection layer is formed using a colloid solution of poly(styrenesulfonic acid) (PSS) and polyethylenedioxythiophene (DEPOT) or a colloid solution of poly(styrenesulfonic acid) and polyaniline which uses water as a main solvent. These inks made of the colloid aqueous solution possess large surface tension of approximately 72 mN/m so long as such a state is held and hence, the inks are hardly ejected from the nozzle of the ink jet device. Further, even when the ink is ejected, ink liquid droplets hardly become wet and are spread on an electrode (ITO) which constitutes the pixel portion. Accordingly, as shown in patent document 1, there has been proposed a method which reduces surface tension by adding alcohol of a low boiling point or glycol-ether based acetic acid of a high boiling point.

In patent document 1, alcohol is added for the purpose of controlling surface tension and viscosity of the ink which forms the hole injection layer in the pixel portion of the organic EL panel and hence, the sufficient consideration is not taken with respect to the relationship between an addition quantity of alcohol and clogging of the nozzle. Accordingly, it is necessary to add 1,3-imidazolidinone of a high boiling point to suppress the nozzle clogging. However, 1,3-imidazolidinone exhibits affinity with polymer and conductive polymer in a binder which constitutes the hole injection layer and hence, it is difficult to acquire the sufficient film-thickness uniformity of the formed hole injection layer. Further, when the organic material is used for forming another organic layer which constitutes the pixel portion of the organic EL panel, the thin film transistor which drives the pixel or the thin film of an active region of other similar electronic device, it is difficult to form the thin film which constitutes the active region with a uniform film thickness.

Accordingly, the present invention has been made to overcome the above-mentioned drawbacks and it is an object of the present invention to provide a manufacturing method of an electronic device using an ink jet method for forming various thin films in an electronic device such as an organic EL panel or an organic thin film transistor, and ink composition suitable for such manufacturing method.

Inventors of the present invention have studied an additive which can satisfy both of the suppression of volatile property of ink and the reduction of surface tension of ink for controlling clogging of water-based ink in a nozzle and for spreading discharged ink liquid droplets in a wet form over an electrode (made of IOT or the like) which constitutes a pixel portion of an organic EL panel, for example. As a result, the inventors of the present invention have found out that tertiary-alcohol which is well mixed with water is effective as the additive. As such alcohol, tertiary-butylalcohol, 3-methyl-1-butyn-3-ol or the like can be named. As also described in the above-mentioned patent document 1, the addition of alcohol into this type of ink has been conventionally known and it has been considered that nozzle clogging occurs unless the addition concentration is approximately 20 wt % or less.

However, inventors of the present invention have studied the structure of alcohol and an addition quantity of alcohol in detail and, eventually, have found out that when approximately 25 wt % or more of tertiary-alcohol is added with respect to a moisture content in the water-based ink, it is possible to spread ink liquid droplets over the electrode of the pixel portion by coating and, at the same time, even when ink is ejected for a long time, nozzle clogging is not generated. Further, when the addition quantity of alcohol is approximately 40 wt % or more, the dispersibility of colloid in the ink is lowered thus precipitating a solid component. Accordingly, the addition quantity of alcohol of approximately 40 wt % or more is not favorable.

The present invention has been made based on the above-mentioned finding and manufactures an electronic device such as an organic layer (active layer related to the light emitting function) which forms a pixel portion of a hole injection layer or the like of an organic EL panel or a channel layer (or a channel region, hereinafter referred to as an active layer) of an organic thin film transistor using ink composition which is formed by adding tertiary-alcohol into ink which uses water as a main solvent. As the tertiary-alcohol, tertiary-butylalcohol, 3-methyl-1-butyn-3-ol or the like may be used. An addition quantity of alcohol is set such that solubility of alcohol with respect to an ink composition is set to a value which falls within a range from approximately 25 wt % to 40 wt %.

According to the present invention, it is possible to suppress clogging of a nozzle of an ink jet device, and active layers of various types of electronic devices can be formed with uniform film thicknesses. Particularly, by applying the ink having the composition of the present invention to the formation of the hole injection layer which constitutes the pixel portion of the organic EL panel, it is possible to largely improve the uniformity of light emission of the whole surface of the display region of polymer organic EL panel and the life times of the elements.

Further, by applying the present invention to the formation of the source electrode and the drain electrode of the organic thin film transistor, it is possible to obtain the organic thin film transistor which exhibits favorable operational properties. Further, it is needless to say that the present invention is applicable to various electronic devices which require the formation of similar organic thin films.

Here, the present invention is not limited to the above-mentioned manufacturing method and various modifications are conceivable without departing from a technical concept of the present invention described in claims.

### BRIEF DESCRIPTION OF THE DRAWINGS

FIG. 1 is a view showing the volatile property of water which is a main solvent of hole injection layer forming ink, tertiary-butylalcohol (tertiary-butanol), xylene and butylbenzoate which is applicable as a light emitting layer of an ink solvent;

FIG. 2 is a view showing the volatile property of water, tertiary-butylalcohol and an aqueous solution containing 30 wt % of tertiary-butylalcohol;

FIG. 3 is a view showing the volatile property of a tertiary-butylalcohol aqueous solution when an initial liquid droplet weight is set to 0.25 mg;

FIG. 4 is a cross-sectional view for explaining a structural example of the vicinity of one pixel of an organic EL panel which is manufactured in an example 1;

FIG. 5 is a view showing an example of the circuit constitution of the organic EL panel to which the present invention is applied;

FIG. 6 is a view showing an example of the cross-sectional structure of an organic thin film transistor to which the present invention is applied;

FIG. 7 is a schematic view for explaining the manner of forming a conductive layer which constitutes the organic thin film transistor explained in FIG. 6 by an ink-jet method using ink of the present invention;

FIG. 8 is a view showing the molecular structure for explaining one example of a polymer material which constitutes an electrode material of the organic thin film transistor explained in FIG. 6;

FIG. 9 is a view showing the molecular structure for explaining one example of a polymer material which forms a semiconductor layer PSI of the organic thin film transistor explained in FIG. 6;

FIG. 10 is a view showing the molecular structure for explaining one example of a polymer material which constitutes an insulation material GI of the organic thin film transistor explained in FIG. 6; and

FIG. 11A to FIG. 11C are schematic views for explaining steps in which ink clogging is generated in a nozzle of an ink jet device.

### DESCRIPTION OF THE PREFERRED EMBODIMENTS

Hereinafter, the present invention is explained in detail in conjunction with drawings showing embodiments.

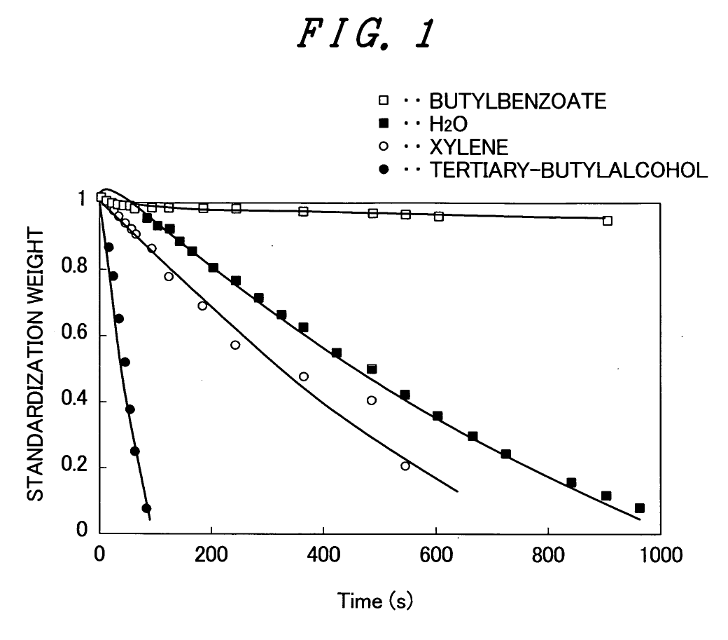

First of all, prior to the explanation of the embodiments, the suppression of the volatile property of a colloid aqueous solution containing PSS and PEDOT by the present invention is explained in detail in conjunction with FIG. 1 to FIG. 5. Here, FIG. 1 to FIG. 5 are views showing a change of weight of liquid droplets after placing liquid droplets of various kinds of colloid aqueous solutions containing PSS and PEDOT on a Teflon sheet in a still state used for forming a nozzle of an ink jet device using a micro syringe. In the drawing, time (s) is taken on an axis of abscissas and a standardized weight is taken along an axis of ordinates.

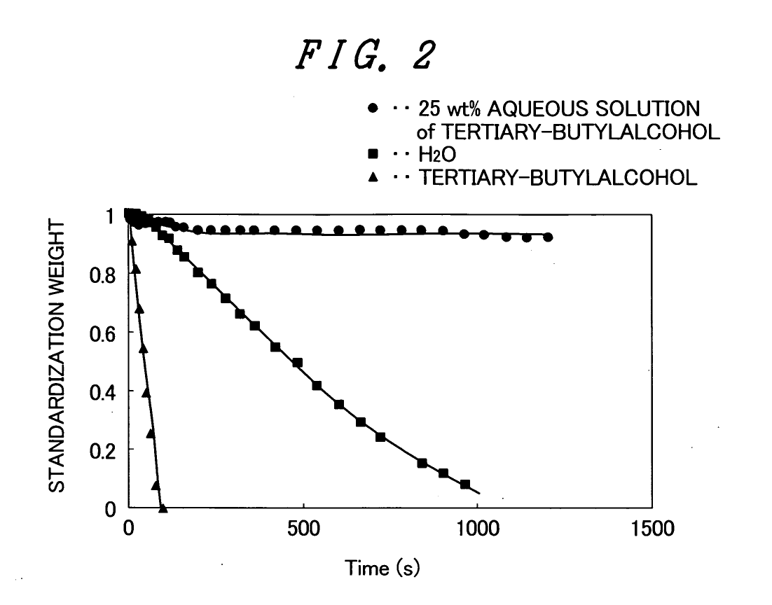

FIG. 1 is a view showing the volatile property of water which is a main solvent of hole injection layer forming ink, tertiary-butylalcohol (tertiary-butanol), xylene and butylbenzoate which is applicable as a light emitting layer of an ink solvent. FIG. 2 is a view showing the volatile property of water, tertiary-butylalcohol and an aqueous solution containing 30 wt % of tertiary-butylalcohol. FIG. 1 shows that butylbenzoate which constitutes one of the ink solvents which do not generate nozzle clogging exhibits an extremely small change of weight and the low volatile property after placing the liquid droplets in a still state. On the other hand, from FIG. 1, it is understood that when the xylene is used as a solvent of the light emitting layer ink, the volatile property of xylene which clogs the nozzle is increased. The volatile property of water is substantially equal to the volatile property of xylene and hence, when ink which uses water as a main solvent in the formation of the hole injection layer, there exists a possibility that the nozzle clogging occurs, and the inventors confirm the nozzle clogging in an actual operation. Further, tertiary-butylalcohol which is one of lower alcohol is volatile at a speed considerably faster than a volatilization speed of water.

It is understood from above that, as described in patent document 1, it is estimated that the addition of tertiary-butylalcohol into the colloid aqueous solution containing PSS and PEDOT produces ink which has the larger volatile property than water. However, upon studying the relationship between an addition quantity and the volatile property of tertiary-butylalcohol, the inventors of the present invention have found out that an aqueous solution which contains tertiary-butylalcohol at an addition concentration of approximately 25 wt % which is shown in FIG. 2 as an example hardly becomes volatile.

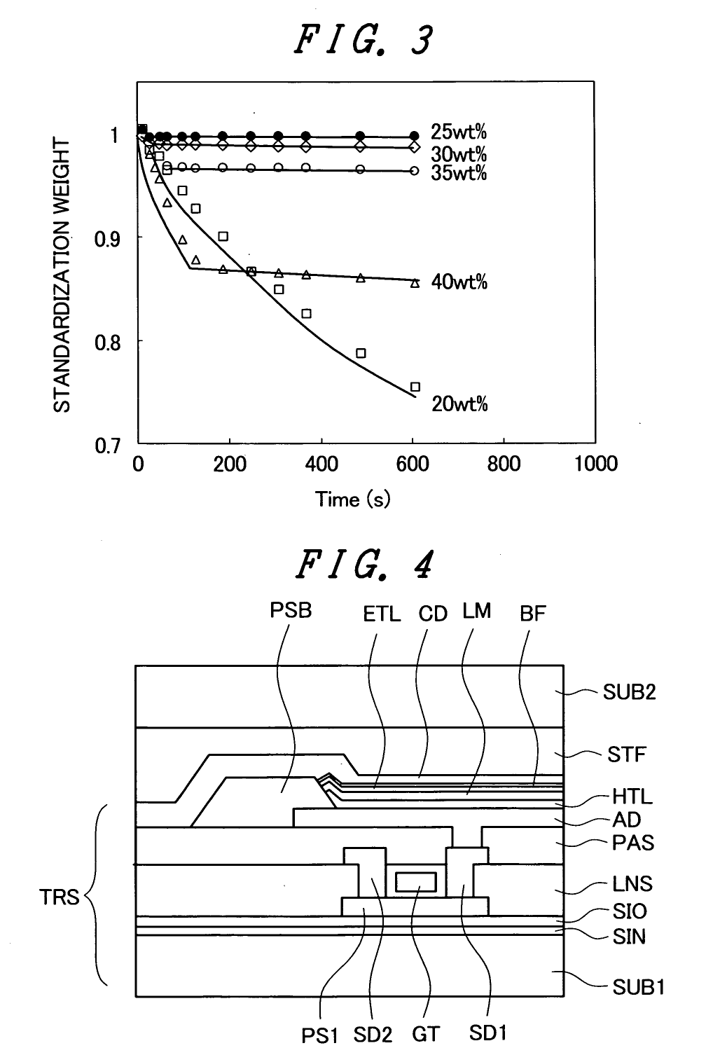

FIG. 3 is a view showing a result of the estimation of the concentration and the volatile property of tertiary-butylalcohol. As can be understood from FIG. 3, the volatile property is suppressed when the concentration of tertiary-butylalcohol is approximately 25 wt % or more.

Further, the inventors of the present invention have confirmed that the use of 3-methyl-1-butyn-3-ol can also suppress the volatile property of water in the same manner as tertiary-butylalcohol. Still further, when the hole injection layer is formed by an ink jet method using ink which is produced by adding tertiary-alcohol at an addition concentration of 25 wt % to the colloid aqueous solution containing PSS and PEDOT, it is confirmed that no nozzle clogging occurs and the hole injection layer having the high film thickness uniformity can be formed.

In the manufacture of the organic EL panel by a vacuum vapor deposition method, there exist drawbacks that the productivity is low and the utilization efficiency of the material is low thus largely pushing up a manufacturing cost. According to the present invention, the manufacture of a polymer organic EL panel whose application to a large-sized display panel is expected becomes possible and hence, the large reduction of manufacturing cost of the organic EL panel can be realized and, at the same time, it is possible to achieve the light emission uniformity and the large extension of lifetime of the organic EL panel.

Here, while the present invention is most effectively applicable to the production of the organic EL panel which is applicable to the large-sized display, the hole injection layer which is formed by applying the ink composition of the present invention has the high electric conductivity and hence, the present invention is also applicable to the formation of source electrodes, drain electrodes (drain lines), gate electrodes (gate lines) and the like of the organic thin film transistors by an ink jet method described in the non-patent document 1, for example.

### Embodiment 1

Ink which is produced by adding approximately 25 wt % of tertiary-butylalcohol into a water-based hole injection layer forming material (an aqueous solution containing PEDOT and PSS) is ejected to a luster sheet using an ink jet device, and nozzle clogging is evaluated by observing a dot-like thin film formed on the luster sheet using a microscope. As a result of the evaluation, it is found out that no nozzle clogging occurs even when the ink is continuously ejected for approximately 60 minutes.

Ink having the same composition as the above-mentioned ink is ejected to a thin-film-transistor (TFT) attached substrate (anode being made of ITO) having a nominal size of 2.1 inches which constitutes a polymer (polyimide) barrier wall having liquid repellency by an ink jet method thus selectively forming a hole injection layer on a pixel portion ITO.

However, no defects attributed to ink clogging is recognized in the hole injection layer. The substrate on which the hole injection layer is formed is subjected to heat treatment at a temperature of approximately 200° for 10 minutes thus evaporating a solvent. When the film thickness distribution of the hole injection layer is measured, it is found out that the thin film with high flatness is formed (see FIG. 3). Ink which is produced by dissolving approximately 0.5 wt % of green light emitting fluorine-polymer in dichlorobenzene is ejected to pixel portions on the substrate on which green light emitting layers are to be formed from a nozzle of an ink jet device thus forming green light emitting layers. In the same manner, blue light emitting layers and red light emitting layers are formed by an ink jet method and, thereafter, these light emitting layers are subjected to heat treatment at a temperature of approximately 120° for 10 minutes thus evaporating an ink solvent.

Using a vapor deposition device which is arranged in a glove box, on a thin-film-transistor attached substrate on which the light emitting layers are formed, a Ca layer having a film thickness of 10 nm and an Al layer having a film thickness of 80 nm are stacked to form a cathode CD. Further, in the glove box, the light emitting portions are sealed with sealing cans containing a desiccant therein thus preparing an organic EL panel element. When a voltage is applied to the prepared organic EL panel, it is found out that the organic EL panel exhibits the favorable color image display characteristic with no light emitting defect.

### COMPARATIVE EXAMPLE 1

Except for that the hole injection layer is formed by the ink to which methyl alcohol is added in place of tertiary-butylalcohol in the embodiment 1, in this comparison example 1, the ink is ejected in the same manner as the embodiment 1. When an ink ejection state is observed with a camera under the illumination of a flash lamp, it is found out that the nozzle is clogged within several minutes after starting the ejection. It is also found that when ink to which ethanol is added in place of methanol is used, the nozzle is clogged within several minutes after starting the ejection.

FIG. 4 is a cross-sectional view for explaining a structural example of the vicinity of one pixel of an organic EL panel which is manufactured in an example 1. In FIG. 4, a thin-film-transistor (TFT)-attached substrate TRS forms a silicon nitride film SIN and a silicon oxide film SIO on an inner surface of the glass substrate SUB1 as a background layer. Thin film transistors TFT each of which is formed of a poly-silicon semiconductor layer PSI, a gate electrode GT, a gate insulation film GI, a source electrode SD1 and a drain electrode SD2 are formed on the background layer. An anode AD made of ITO is formed on a passivation layer PAS and is connected with the source electrodes SD1 via through holes.

On the anode AD made of ITO, hole injection layers HTL are formed by applying ink having the above-mentioned composition using a nozzle of an ink jet device. Light emitting layers LM having specified colors are applied to the hole injection layers HTL using an ink jet device. A Ca layer BF is formed on the light emitting layer LM by vapor deposition and an AL layer is formed on the Ca layer by vapor deposition thus forming a cathode CD. Further, depending on materials of the hole injection layer HTL and the light emitting layer LM, a hole transport layer may be inserted between the hole injection layer HTL and the light emitting layer LM or an electron transport layer and an electron injection layer may be inserted between the light emitting layer LM and the cathode CD in these order.

The thin-film-transistor (TFT)-attached substrate TRS having the above-mentioned structure is hermetically sealed by a sealing plate SUB2. In the example shown in FIG. 4, a filling material made of an epoxy resin is arranged between the cathode CD of the thin-film-transistor (TFT)-attached substrate TRS and the sealing plate SUB2. However, a gap defined between the substrate TRS and the sealing plate SUB2 may be used as a dry space. To maintain the dry space, it is desirable to arrange a desiccant in place between both substrates.

FIG. 5 is a view showing an example of the circuit constitution of the organic EL panel to which the present invention is applied. As shown in FIG. 5, a plurality of data lines DL (DL(m+1), DL(m), DL(m−1) . . . ) and a plurality of gate lines GL (GL(n+1), GL(n), GL(n−1) . . . ) are wired in a matrix array on a display region DIP as shown in FIG. 5. In a pixel PX which is surrounded by the respective data lines DL and the respective gate lines GL, a thin film transistor SW1 which constitutes a switching element (control transistor), a thin film transistor SW2 which constitutes a current supply transistor (drive transistor), a capacitor C for holding data and an organic EL element OLE are arranged.

The thin film transistor element SW1 has a control electrode (gate) connected to the gate line GL and one end of a channel thereof connected to the data line DL. A gate of the thin film transistor SW2 is connected to another end (source) of the channel of the thin film transistor SW1, and one electrode (+electrode) of the capacitor C is connected to the connection point. The thin film transistor SW2 has one end (drain) of a channel thereof connected to a current supply line PL and another end (source) connected to an anode of the organic EL element OLE. The data lines DL are driven by a data drive circuit DDR and the scanning lines (gate lines) GL are driven by a scanning drive circuit DDG. Further, the current supply line PL is connected with a current supply circuit PW via a common potential supply bus line PLA.

In FIG. 5, when one pixel PX is selected by the scanning line GL and the thin film transistor SW1 of the pixel PX is turned on, image data supplied to the pixel PX from the data line DL is stored in the capacitor C. Then, at a point of time that the thin film transistor SW1 is turned off, the thin film transistor SW2 is turned on and a current flows into the organic EL element OLE from the current supply line PL during a substantially 1 frame period. The current which flows in the organic EL element OLE is regulated by the thin film transistor SW2, while a voltage corresponding to a charge stored in the capacitor C is applied to a gate of the thin film transistor SW2. By controlling these thin film transistors SW1, SW2 with respect to the whole device, it is possible to control the light emission of a plurality of pixels and hence, a two-dimensional image is reproduced in a display region DIP.

### Embodiment 2

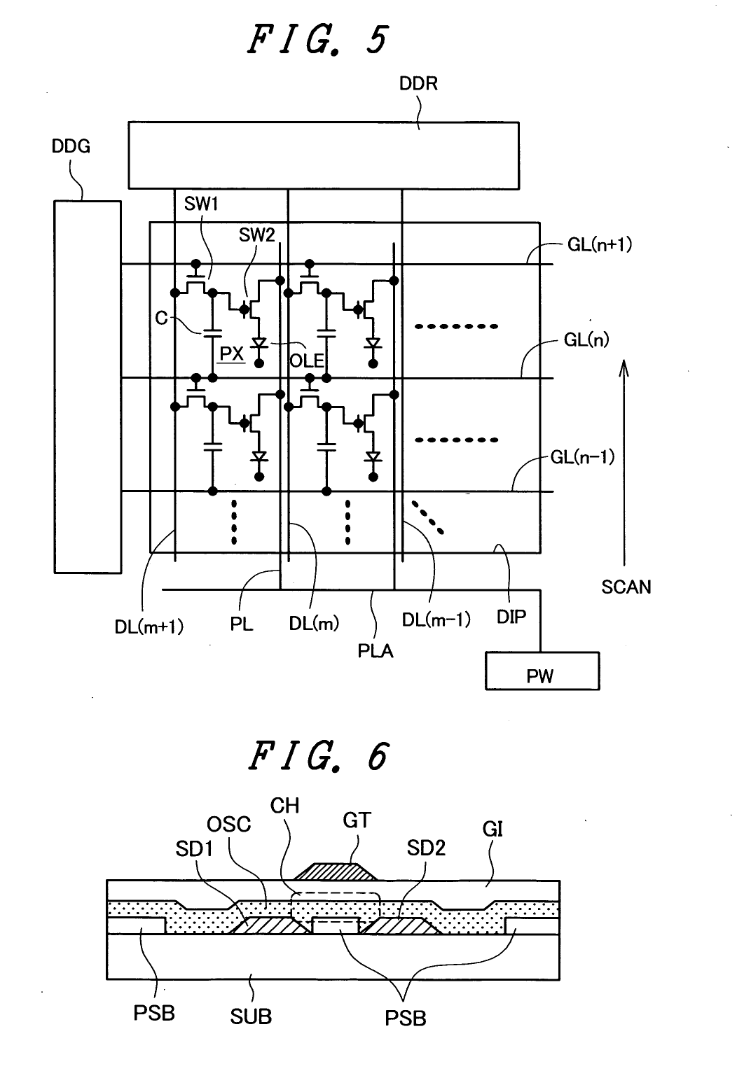

FIG. 6 is a view showing an example of the cross-sectional structure of an organic thin film transistor to which the present invention is applied. Here, the structure of the organic semiconductor is constituted by modifying the structure described in non-patent document 1. Here, a substrate SUB is used as a glass substrate, while a separator PSB is made of an acrylic resin. The organic thin film transistor is formed by applying a positive photoresist based on acrylic resin (made by JSR) to the glass substrate SUB and by forming a pattern of the separator PSB which separates a source electrode SD1 and a drain electrode SD2 using an acrylic resin layer by a photolithography method.

Next, after making the acrylic resin layer insoluble to a solvent by heat treatment, a separation layer is made liquid repellant due to a CF₄ fluorine plasma treatment. Ink which is produced by adding butanol of approximately 25 wt % of solubility to a water dispersed liquid containing PEDOT/PSS is ejected between patterns of acrylic resin from a nozzle of an ink jet device, and heated and dried thus forming source electrodes SD1 and drain electrodes SD2 made of PEDOT/PSS.

Next, a xylene solution containing fluorene polymer (molecular weight: 300,000) is applied to the glass substrate SUB on which the source electrodes and the drain electrodes are formed by a spinning method, and the coated xylene solution is subjected to heat treatment at a temperature of approximately 200° C. under nitrogen atmosphere thus forming a semiconductor layer. An isopropanol solution containing polyvinylphenol (molecular weight: 200,000) is applied to the semiconductor layer by a spinning method to form an insulation layer GI. Here, symbol CH indicates a channel region. The insulation layer GI is made liquid-repellant by CF₄ fluorine plasma treatment, and a KrF excimer laser beams are radiated to an insulation layer right above the acrylic resin pattern which constitutes the separator PBS thus dissipating the liquid repellency of regions where gate electrodes are formed. Next, ink which is produced by adding tertiary-butylalcohol of solubility of approximately 25 wt % into the water dispersed liquid containing PEDOT/PSS is ejected to regions where the gate electrodes are formed by an ink jet method, and the ink is heated and dried to form gate electrodes. A protective film and the like which are formed thereafter are omitted from the drawing. When the properties of the organic thin film transistor which is prepared in this manner are evaluated, the thin film transistor exhibits favorable properties.

In the above-mentioned embodiment, the formation of the source electrode, the drain electrode and the gate electrode which constitute conductive layers of the thin film transistor which are common in requiring patterning is performed by an inkjet method, wherein the formation of the semiconductor layer and the insulation layer is performed by a spin coating method. Here, in forming the source electrodes and the drain electrodes using the separator PSB which constitutes the pattern of acrylic resin as guides or in forming the gate electrodes using portions which suppress the ink repellency of an upper surface of an insulation layer as guides, the ink composition having the composition of the present invention is used.

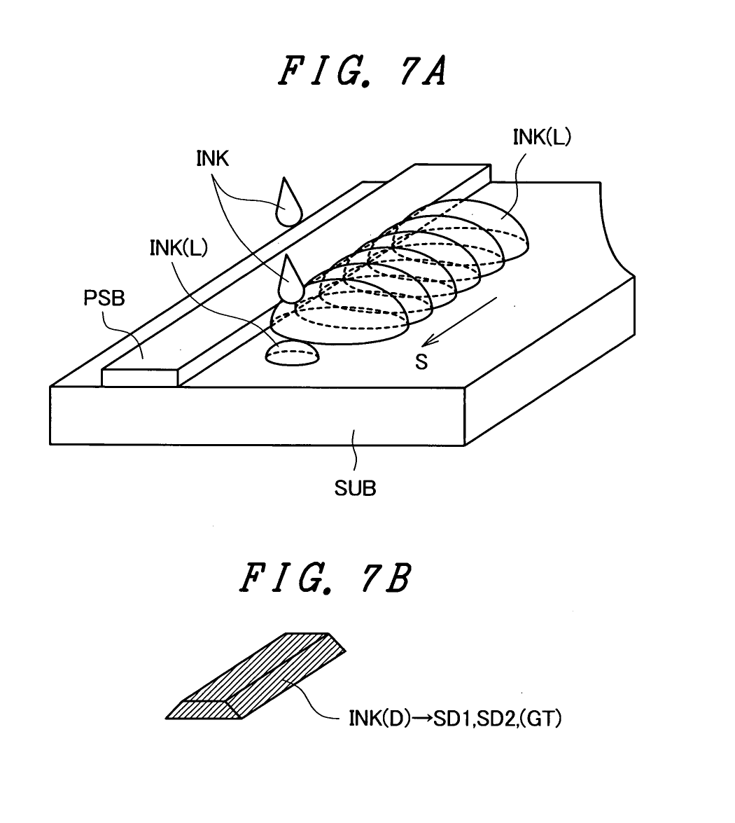

FIG. 7A and FIG. 7B are schematic views for explaining the manner of forming a conductive layer which constitutes the organic thin film transistor explained in FIG. 6 by an ink-jet method using ink of the present invention. In FIG. 7A, ink of an electrode material which has the composition of the present invention is ejected from a nozzle of an ink jet device along the electrode forming portion of the glass substrate SUB where the separator PSB is arranged. In FIG. 7A, liquid droplets of ejected ink and ink in a liquid form after being dropped on the glass substrate SUB are indicated by INK(L). While scanning nozzles in the direction indicated by an arrow S, ink is ejected. The undesired spreading of ejected ink INK(L) on the glass substrate SUB is suppressed by the separator PSB and hence, the liquid droplets are bonded to each other and are continuously applied in the scanning direction of the nozzle. Thereafter, the liquid droplets are solidified by heating and drying and hence, a strip-like electrode (source electrode SD1, drain electrode SD2 or gate electrode GT) is formed as shown in FIG. 7B. Here, the solidified ink is indicated by reference symbol INK(D).

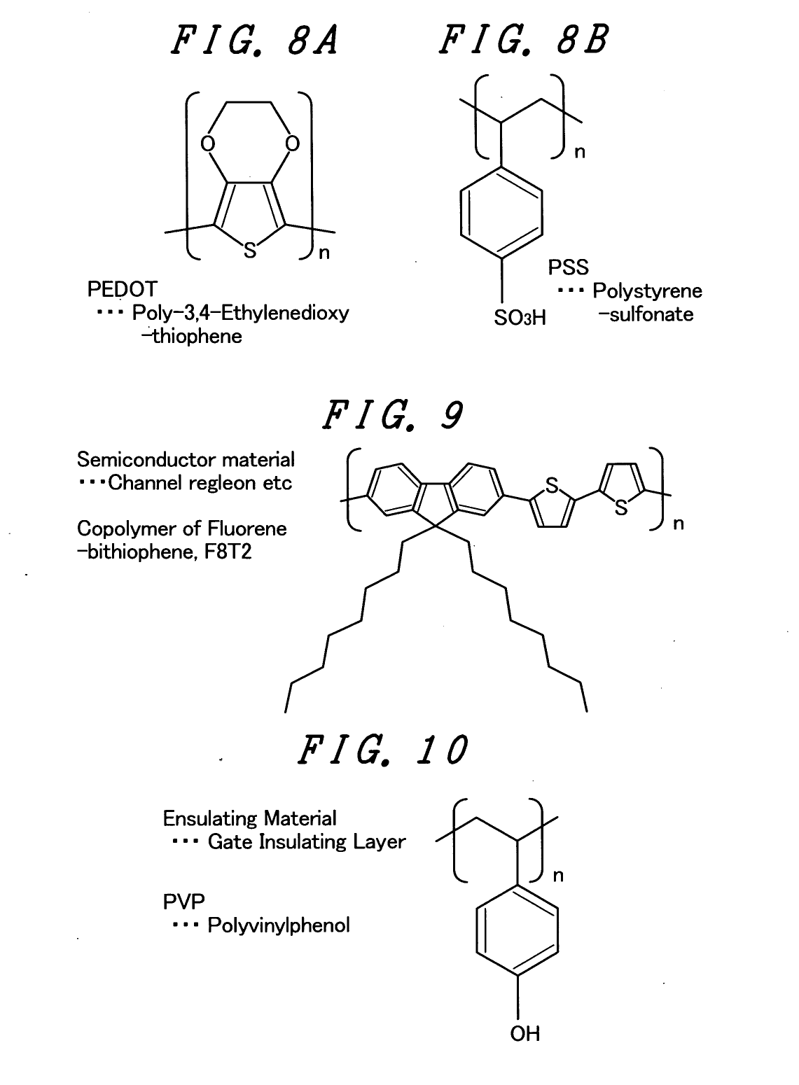

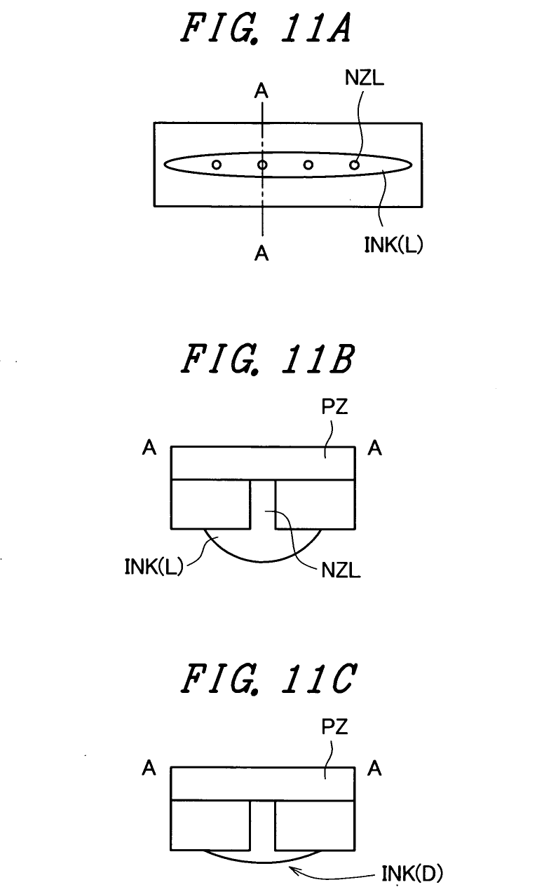

FIG. 8A and FIG. 8B are views showing the molecular structures for explaining one example of polymermaterials which constitute electrode materials of the organic thin film transistor explained in FIG. 6, wherein this type of electrode material is formed of PEDOT and PSS. FIG. 8A indicates the molecular structure of PEDOT and FIG. 8B indicates the molecular structure of PSS.

FIG. 9 is a view showing the molecular structure for explaining one example of a polymer material which forms a semiconductor layer PSI of the organic thin film transistor explained in FIG. 6. The material of the semiconductor layer PSI is fluorene-bithiophene as described above and has the molecular structure shown in FIG. 9.

FIG. 10 is a view showing the molecular structure for explaining one example of a polymer material which constitutes an insulation material GI of the organic thin film transistor explained in FIG. 6. The insulation material GI is a so-called gate insulation layer and is polyvinyl phenol. The molecular structure is shown in FIG. 9.

What is claimed is:

1. A manufacturing method of an electronic device which realizes the predetermined functional structure which is formed by stacking or arranging in parallel a plurality of active layers or stacking and arranging in parallel a plurality of active layers, wherein
at least one layer of the plurality of active layers is formed by applying water ink which is prepared by adding tertiary-alcohol to a material which constitutes the active layer using an ink jet method.

2. A manufacturing method of an electronic device according to claim 1, wherein the tertiary-alcohol is 3-methyl-1-butyn-3-ol.

3. A manufacturing method of an electronic device according to claim 2, wherein an addition quantity of the tertiary-alcohol falls within a range from 25 wt % to 40 wt % with respect to the ink.

4. A manufacturing method of an electronic device, wherein the electronic device is an organic EL panel which is formed by arranging a large number of organic EL elements on an insulation substrate, the manufacturing method comprising the steps of
forming first electrodes for respective pixels on the insulation substrate; and
forming an organic material which forms a plurality of pixel portion forming layers made of an organic material which contribute to the emission of light to the first electrodes;
forming second electrodes such that the second electrodes cover the pixel portion forming layers; whereby
at least one layer of the pixel portion forming layers is formed by applying water ink to which tertiary-alcohol is added by an ink jet method.

5. A manufacturing method of an electronic device according to claim 4, wherein the tertiary-alcohol is 3-methyl-1-butyn-3-ol.

6. A manufacturing method of an electronic device according to claim 5, wherein an addition quantity of the tertiary-alcohol falls within a range from 25 wt % to 40 wt % with respect to the ink.

7. A manufacturing method of an electronic device according to claim 5, wherein at least one layer of the pixel portion forming layers is a hole injection layer.

8. A manufacturing method of an electronic device, wherein the electronic device is an organic thin film transistor which forms source electrodes, drain electrodes, semiconductor layers and gate electrodes on an insulation substrate, wherein at least any one of the source electrodes, the drain electrodes and the gate electrodes is formed by applying water ink into which tertiary-alcohol is added by an ink jet method.

9. A manufacturing method of an electronic device according to claim 8, wherein the tertiary-alcohol is 3-methyl-1-butyn-3-ol.

10. A manufacturing method of an electronic device according to claim 9, wherein an addition quantity of the tertiary-alcohol falls within a range from 25 wt % to 40 wt % with respect to the ink.
